(19) United States
(12) Patent Application Publication
(10) Pub. No.: US 2001/0043044 A1
(43) Pub. Date: Nov. 22, 2001

(54) Organic electroluminescence element

(76) Inventors: Takeo Wakimoto, Tsurugashima-shi (JP); Teruichi Watanabe, Tsurugashima-shi (JP); Kenji Nakamura, Tsurugashima-shi (JP)

Correspondence Address: SUGHRUE, MION, ZINN, MACPEAK & SEAS, PLLC, 2100 PENNSYLVANIA AVENUE, N.W., WASHINGTON, DC, 20037-3213, US

(21) Appl. No.: 09/789,701

(22) Filed: Feb. 22, 2001

(30) Foreign Application Priority Data
Feb. 23, 2000 (JP) 2000-45982

(51) Int. Cl. H01J 1/62; H01J 63/04

(52) U.S. Cl. 313/506; 313/504

(57) ABSTRACT

An organic electroluminescence element comprised of a laminate of an anode, a light emitting layer made of an organic compound, a hole blocking layer made of an organic compound, an electron transport layer made of an organic compound, and a cathode. Additionally, the element has a mixed layer, between the light emitting layer and the hole blocking layer, including a material constituting the light emitting layer and a material constituting the hole blocking layer.

### BACKGROUND OF THE INVENTION

1. Technical Field

The present invention relates to an organic electroluminescence element (hereinafter also referred to as the “organic EL element”) which utilizes the electroluminescence (hereinafter also referred to as the “EL”) of organic compounds which emit light in response to a current injected thereinto, and has a light emitting layer formed of a laminate of such materials.

2. Description of the Related Art

Generally, each of the organic EL elements constituting a display panel using organic materials comprises an anode as a transparent electrode, a plurality of organic material layers including an organic light emitting layer, and a cathode comprised of a metal electrode, which are laminated as thin films in this order on a glass substrate as a display surface. The organic material layers include, in addition to the organic light emitting layer, a layer of a material having the hole transport capability such as a hole injection layer and a hole transport layer, a layer of a material having the electron transport capability such as an electron transport layer and an electron injection layer, and so on. Organic EL elements comprising these layers are also proposed. The electron injecting layer also contains an inorganic compound.

As an electric field is applied to the laminate organic EL element including an organic light emitting layer and an electron or hole transport layer, the holes are injected from the anode, while electrons are injected from the cathode. The electrons and the holes are recombined in the organic light emitting layer to form excitors. The organic EL element utilizes light which is emitted when the excitors return to a base state. In some cases, a pigment may be doped into the light emitting layer for improving the efficiency of light emission and stably driving the element.

For example, a metal complex typified by an Al complex (Alq3) of oxine has the electron transport capability, and blocks holes which are injected from the anode and migrate into the light emitting layer, wherein, however, a portion of the holes migrates to Alq3, so that the holes are not completely blocked.

Thus, for improving the low power consumption nature, light emission efficiency, and driving stability of the organic EL element, it has been proposed to provide a hole blocking layer between the organic light emitting layer and the cathode for limiting the migration of holes from the organic light emitting layer. Efficient accumulation of holes in the light emitting layer with the aid of the hole blocking layer can result in an improved recombination probability with electrons, and a higher light emission efficiency. A report has been made that single use of a triphenyl diamine derivative or a triazole derivative is effective as a hole blocking material (see Japanese Unexamined Patent Publication Nos. Hei 8-109373 and Hei 10-233284).

While the provision of the hole blocking layer is effective for increasing the light emission efficiency of the organic EL element, a longer lifetime of the element is required. There is a need for a highly efficient organic electroluminescence element which continuously emits light at a high luminance with a less current.

### OBJECT AND SUMMARY OF THE INVENTION

It is an object of the present invention to provide an organic EL element which has a hole blocking layer that is capable of confining holes injected from an anode in a light emitting layer, and passing electrons injected from a cathode therethrough to improve the recombination probability of both carriers.

An organic electroluminescence element according to the present invention has a laminate of an anode, a light emitting layer made of an organic compound, a hole blocking layer made of an organic compound, an electron transport layer made of an organic compound, and a cathode. The organic electroluminescence element additionally includes a mixed layer, between the light emitting layer and the hole blocking layer, including a material constituting the light emitting layer and a material constituting the hole blocking layer.

In one aspect of the invention, the organic electroluminescence element further includes one or more layers made of a material having a hole transport capability, disposed between said anode and said light emitting layer, said material including an organic compound.

In another aspect of the invention, the organic electroluminescence element further includes one or more mixed layers made of plural kinds of materials having a hole transport capability, disposed between said anode and said light emitting layer, said material including an organic compound.

In a further aspect of the invention, the organic electroluminescence element further includes an electron injecting layer disposed between said cathode and said electron transport layer.

In a still further aspect of the organic electroluminescence element of the invention, in said mixed layer, one of the electron transport materials is mixed in a proportion ranging from 5 to 95% in weight percentage to all the electron transport materials contained therein.

In another aspect of the organic electroluminescence element of the invention, at least one of said electron transport materials constituting said mixed layer includes, as a main component, an electron transport material having a larger ionization potential than that of said light emitting layer.

In a further aspect of the organic electroluminescence element of the invention, said light emitting layer includes a fluorescence material or a phosphorescence material.

### BRIEF DESCRIPTION OF THE DRAWINGS

FIGS. 1 to 5 are diagrams schematically illustrating organic EL elements.

### DETAILED DESCRIPTION OF THE PREFERRED EMBODIMENTS

An embodiment of the present invention will hereinafter be described with reference to the accompanying drawings.

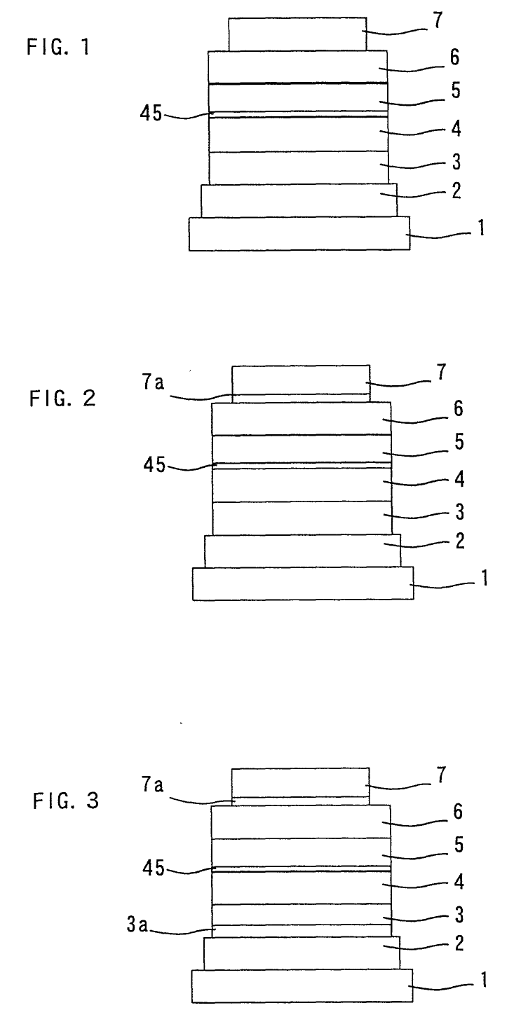

As illustrated in FIG. 1, an organic EL element according to the present invention comprises a transparent anode 2; a hole transport layer 3 made of an organic compound; a light emitting layer 4 made of an organic compound; a hole blocking layer 5 made of an organic compound; an electron transport layer 6 made of an organic compound; and a cathode 7 made of a metal, which are laminated in this order on a transparent substrate 1 such as glass. The organic EL element additionally comprises a mixed layer 45, between the light emitting layer 4 and the hole blocking layer 5, including a material constituting the light emitting layer 4 and a material constituting the hole blocking layer 5.

In addition to the foregoing structure, another organic EL element may have a structure which includes an electron injecting layer 7a laminated or deposited as a thin film between the electron transport layer 6 and the cathode 7, as illustrated in FIG. 2.

Further alternatively, as illustrated in FIG. 3, another organic EL element may include a hole injecting layer 3a laminated or deposited as a thin film between the anode 2 and the hole transport layer 3.

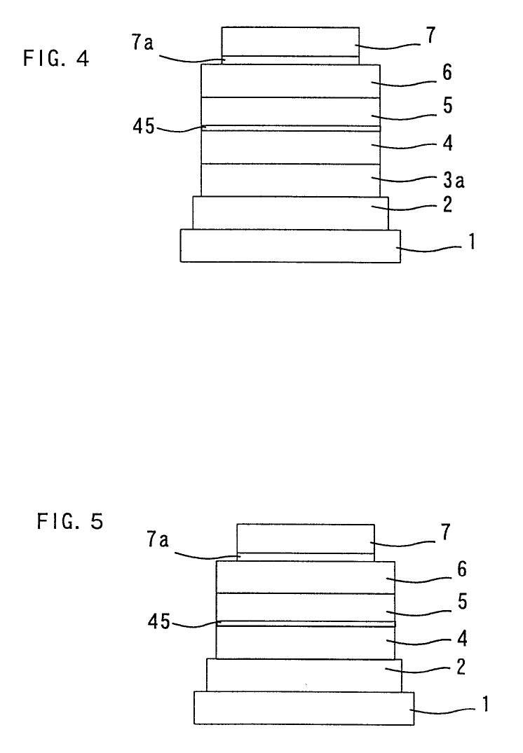

Also, the hole transport layer 3 or the hole injection layer 3a may be omitted from the structures illustrated in FIGS. 1 to 3, provided that the light emitting layer 4 is made of a light emitting material having the hole transport capability. For example, as illustrated in FIGS. 4 and 5, an organic EL element may have a structure comprised of an anode 2, a hole injecting layer 3a, a light emitting layer 4, a mixed layer 45, a hole blocking layer 5, an electron transport layer 6 and a cathode 7 deposited in this order on a substrate 1, or a structure comprised of an anode 2, a light emitting layer 4, a mixed layer 45, a hole blocking layer 5, an electron transport layer 6 and a cathode 7 deposited in this order.

As the cathode 1, there may be used a metal which has a small work function, for example, aluminum, magnesium, indium, silver, and alloys thereof, and a thickness in a range of approximately 100 to 5000 angstrom. Also, as the anode 2, there may be mentioned a conductive material which has a large work function, for example, indium tin oxide (hereinafter abbreviated as “ITO”), and a thickness in a range of approximately 1000 to 3000 angstrom, or gold of approximately 800 to 1500 angstrom in thickness. It should be noted that when gold is used as an electrode material, the electrode is translucent. Either the cathode or the anode may be transparent or translucent.

In this embodiment, the mixed layer 45 laminated between the light emitting layer 4 and the hole blocking layer 5 is a mixed layer made by mixing a material used for the light emitting layer 4 and an electron transport material used for the hole blocking layer 5 by coevaporation or the like, and deposited. Further, one or more kinds of electron transport materials may be mixed with the mixed layer 45. The electron transport materials having the electron transport capability may be selected from materials represented by the following chemical formulae. The electron transport material is selected as a material whose ionization potential is larger than the ionization potential of the light emitting layer. In the mixed layer 45, one of the electron transport materials is preferably mixed in the proportion of 5 to 95% in weight percentage to all the electron transport materials.

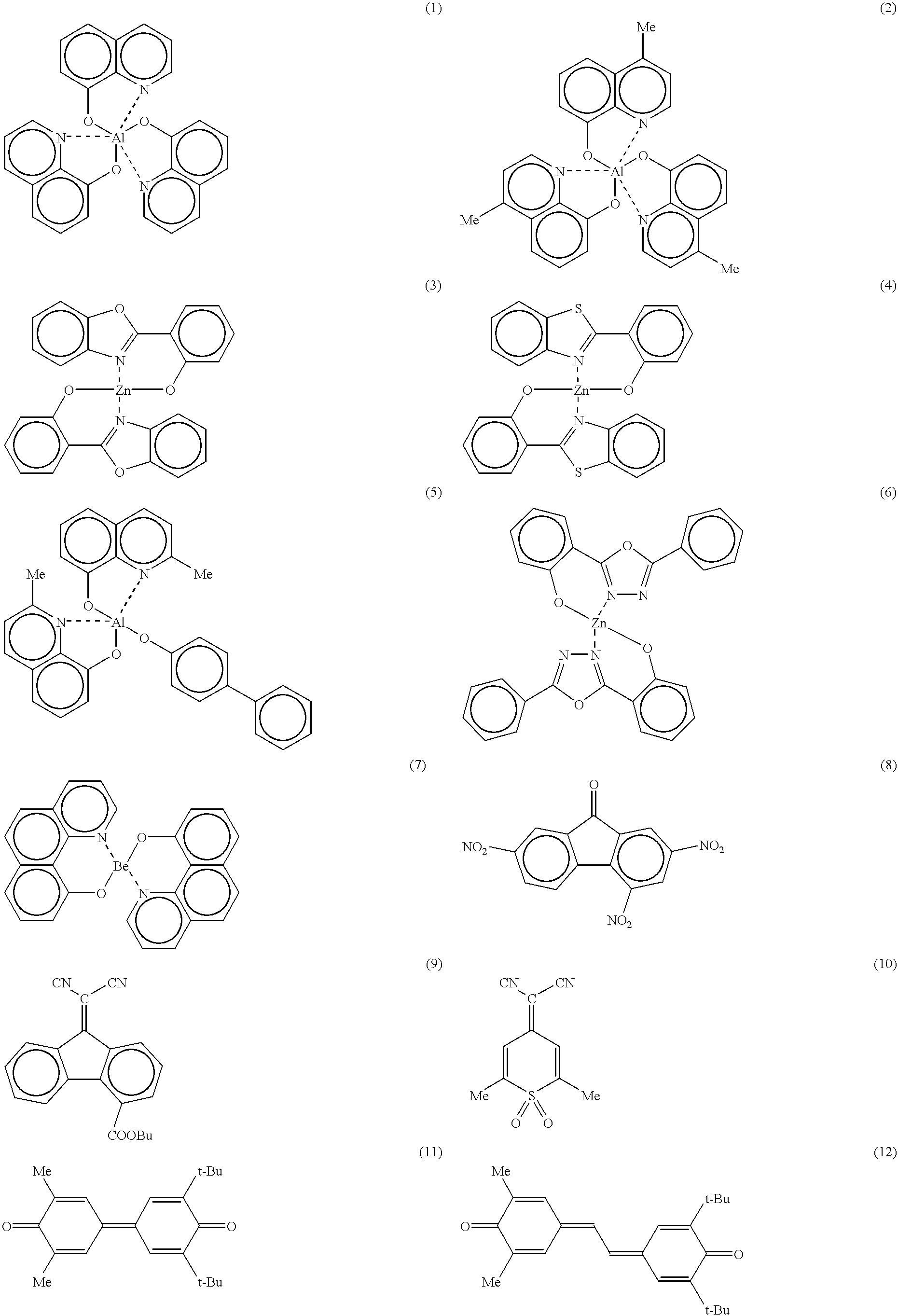

In this embodiment, components contained in the light emitting layer 4 may be, for example, materials having the hole transport capability as represented by the following chemical formulae:

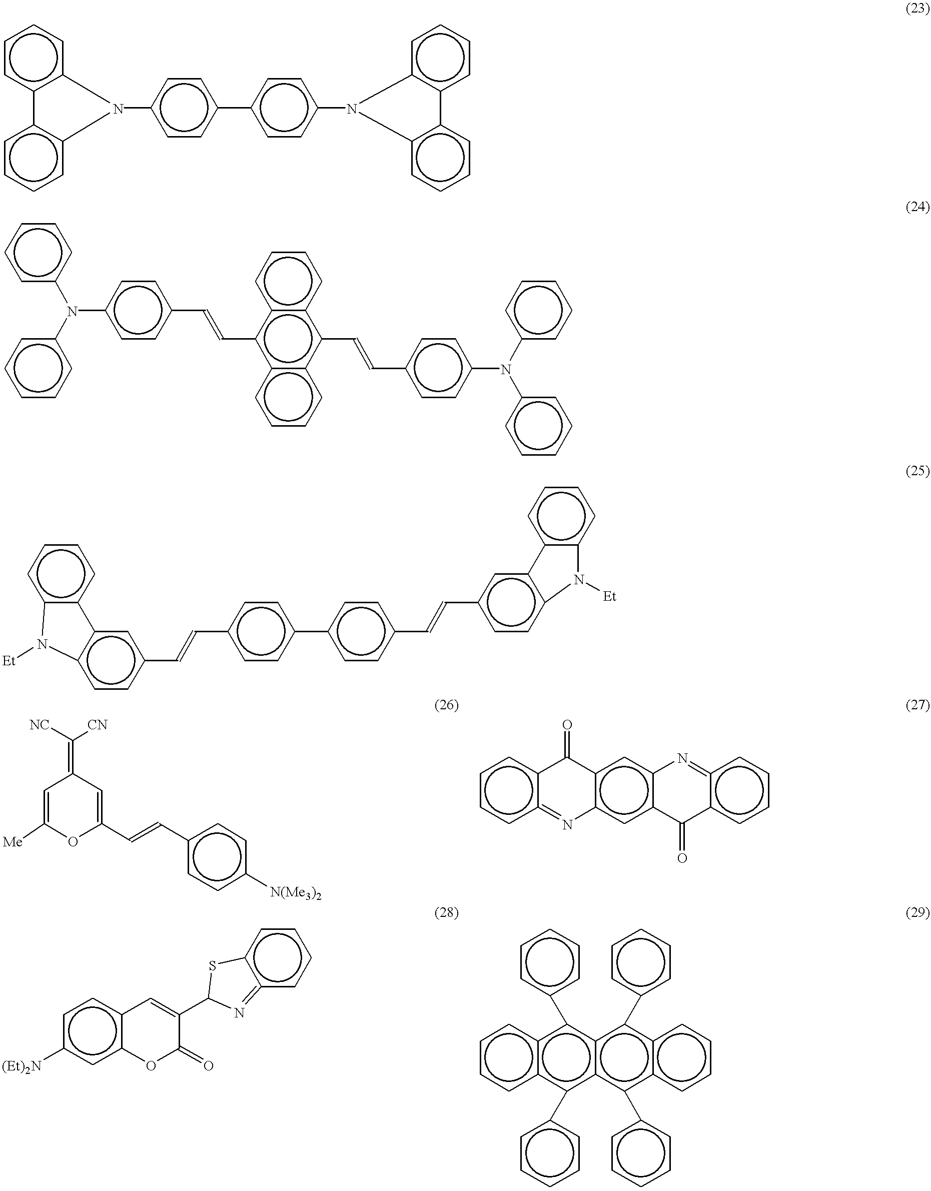

In the above formulae, Me represents a methyl group; Et represents an ethyl group; Bu represents a butyl group; and t-Bu represents a tert-butyl group. The light emitting layer 4 may contain materials other than those shown in the foregoing chemical formulae. Also, the light emitting layer may be doped with a coumarin derivative having a high fluorescence quantum efficiency (Chemical Formula 28), a fluorescent material such as quinacridone derivatives (Chemical Formula 30) to (Chemical Formula 32), or phosphorescence materials (Chemical Formula 26) to (Chemical Formula 32).

In this embodiment, the material constituting the hole injecting layer 3a or the hole transport layer 3 may be selected, for example, from the materials having the hole transport capability represented by (Chemical Formula 33) to (Chemical Formula 49). Alternatively, the hole injecting layer and the hole transport layer disposed between the anode and the light emitting layer may be formed as a mixed layer by coevaporating a plurality of materials made of organic compounds having the hole transport capability, and one or more of such mixed layers may be provided. In this way, one or more layers containing a material including an organic compound having the hole transport capability may be disposed between the anode and the light emitting layer as a hole injecting layer or a hole transport layer.

Several organic EL elements were specifically made for evaluating their characteristics.

### COMPARATIVE EXAMPLE 1

The respective thin films were laminated on a glass substrate formed with an anode made of ITO having a thickness of 1100 Å by a vacuum deposition method at the degree of vacuum of 5.0×10⁻⁶ Torr.

First, N,N′-diphenyl-N,N′-(3-methylpheyl)-1,1′-biphenyl-4,4′-diamine (hereinafter abbreviated as “TPD”) represented by (Chemical Formula 34) was formed in a thickness of 400 Å on the ITO anode as a hole injecting layer at the deposition rate of 3 Å/sec.

Next, 4,4′-N,N′-dicarbasol-biphenyl (hereinafter abbreviated as “CBP”) represented by (Chemical Formula 23) and tris(2-phenylpyridine) iridium (hereinafter abbreviated as “Ir(PPY)3”) represented by (Chemical Formula 32) were coevaporated from different evaporation sources on the hole injecting layer as a light emitting layer. In this event, the concentration of Ir(PPY)3 in the light emitting layer was 6.5 wt %. The CBP was deposited at the deposition rate of 5 Å/sec.

Further, on the light emitting layer, 2,9-dimethyl-4,7-diphenyl-1,10-phenanthroline (hereinafter abbreviated as “BCP”) represented by (Chemical Formula 14) was laminated as a hole blocking layer in a thickness of 100 Å at the deposition rate of 3 Å/sec.

Subsequently, on the hole blocking layer, tris(8-hyroxyquinoline aluminum) (hereinafter abbreviated as “Alq3”) represented by (Chemical Formula 1) was deposited as an electron transport layer in a thickness of 400 Å at the deposition rate of 3 Å/sec.

Further, on the electron transport layer, lithium oxide (Li2O) was deposited as an electron injecting layer in a thickness of 5 Å at the deposition rate of 0.1 Å/sec, and aluminum (Al) was laminated on the electron injecting layer as an electrode in a thickness of 1500 Å at the rate of 10 Å/sec to complete an organic light emitting element.

This element emitted light from Ir(PPY)3. When the element created as described above was driven with a regulated current of 1.2 mA/cm², the luminance half-life was 170 hours (Lo=500 cd/m²).

### EXAMPLE 1

An element was created in a manner similar to Comparative Example 1 except that a mixed layer was disposed between the hole blocking layer and the light emitting layer by coevaporating BCP which is a material constituting the hole blocking layer and CBP which is a material constituting the light emitting layer in a film thickness ratio of 1:1 in a thickness of 100 Å from different evaporation sources.

When this element was driven with a regulated current of 1.2 mA/cm² identical to the current used in Comparative Example 1, the initial luminance was 440 cd/m², and the half-life was significantly improved to 3500 hours.

### COMPARATIVE EXAMPLE 2

An element was created in a manner similar to Comparative Example 1 except that the light emitting layer of Comparative Example 1 was formed only of CBP without coevaporating Ir(PPY)3.

Similar to Comparative Example 1, when this element was driven with a regulated current of 1.2 mA/cm², the half-life was 50 hours.

### EXAMPLE 2

An element of Example 2 was prepared in a similar manner to Comparative Example 2 except that a mixed layer was disposed between the hole blocking layer and the light emitting layer by coevaporating BCP which is a material constituting the hole blocking layer, and CBP which is a material constituting the light emitting layer in a film thickness ratio of 1:1 in a thickness of 100 Å from different evaporation sources.

Similar to Comparative Example 1, when this element was driven with a regulated current of 1.2 mA/cm², the half-life was improved to 730 hours.

As described above, the present invention provides an organic EL element which can be driven to emit light for a long time by virtue of the provision of the mixed layer including a material constituting the light emitting layer and a material constituting the hole blocking layer between the light emitting layer and the hole blocking layer, making it possible to prevent mutual diffusion of the hole blocking layer and adjacent layers due to heat generated during the driving of the organic EL element.

What is claimed is:

1. An organic electroluminescence element having a laminate of an anode, a light emitting layer made of an organic compound, a hole blocking layer made of an organic compound, an electron transport layer made of an organic compound, and a cathode, said element comprising:
a mixed layer between said light emitting layer and said hole blocking layer, said mixed layer including a material constituting said light emitting layer and a material constituting said hole blocking layer.

2. An organic electroluminescence element according to claim 1, further comprising one or more layers made of a material having a hole transport capability, disposed between said anode and said light emitting layer, said material including an organic compound.

3. An organic electroluminescence element according to claim 1, further comprising one or more mixed layers made of plural kinds of materials having a hole transport capability, disposed between said anode and said light emitting layer, said material including an organic compound.

4. An organic electroluminescence element according to claim 1, further comprising an electron injecting layer disposed between said cathode and said electron transport layer.

5. An organic electroluminescence element according to claim 1, wherein in said mixed layer, one of the electron transport materials is mixed in a proportion ranging from 5 to 95% in weight percentage to all the electron transport materials contained therein.

6. An organic electroluminescence element according to claim 1, wherein at least one of said electron transport materials constituting said mixed layer includes, as a main component, an electron transport material having a larger ionization potential than that of said light emitting layer.

7. An organic electroluminescence element according to claim 1, wherein said light emitting layer includes a fluorescence material or a phosphorescence material.
